(19) United States
(12) Patent Application Publication
(10) Pub. No.: US 2016/0161539 A1
(43) Pub. Date: Jun. 9, 2016

(54) ELECTRICITY THEFT DETECTION SYSTEM

(71) Applicant: Powerhive, Inc., Berkeley, CA (US)

(72) Inventor: Steven M. Kraft, Albany, CA (US)

(21) Appl. No.: 14/564,423

(22) Filed: Dec. 9, 2014

(51) Int. Cl. G01R 22/06; G01R 19/00

(52) U.S. Cl. CPC G01R 22/066; G01R 19/0092

(57) ABSTRACT

A method, system, and apparatus for detecting electricity theft are disclosed. Electricity theft is the practice of stealing electrical power from a provider. Violators are not charged for the total number of kilowatt-hours actually used, causing lost revenue for both utility companies and retail electricity providers. The method, system, and apparatus may comprise providing power to a plurality of end user destinations from one power source, selecting one destination for testing, and switching off all of the end user destinations except for the selected destination. The method, system, and apparatus may further comprise sensing the current from the power source, sensing the current returning from the selected destination, and determining the difference. The presence of electricity theft can be determined if the current entering the system is not the same as the current returning from the system.

### BACKGROUND

Electricity theft is the practice of stealing electrical power from a provider. Violators are not charged for the total number of kilowatt-hours actually used, causing lost revenue for both utility companies and retail electricity providers. Theft of electricity may result in higher fees for legitimate electricity customers, who must make up for the lost revenue so that the utility provider can continue to operate. Electricity theft is also dangerous, because the tampering involved can result in fire or electrocution. Electricity theft is a problem in both developed and developing countries.

A basic method of stealing electricity is to attach a wire directly to a main power route, thus bypassing the legitimate purchaser of electricity, so that electricity can flow to the electricity thief without passing through the electric meter installed by agency responsible for providing electrical services.

Electricity theft can also be accomplished by tampering with the electric meter. For example, but injecting foreign elements such as transistors, resistors, or IC chips into the electric meter, the meter can be made to show lower than actual electricity consumption. In other cases, a remotely controlled circuit is installed inside the electricity meter, where the meter can be remotely slowed down. If the remotely controlled circuit is off, it will not be detectable when the meter is tested for accuracy. Electromechanical electricity meters can be tampered with by drilling holes into or otherwise entering the meter and inserting objects into the meter to obstruct the movement of the internal mechanism.

Electricity theft can often be detected by visual inspection of the wires to and from the main power route, or of the electric meter. Automated methods, however, are more practical and scalable, and are able to detect theft methods that might not be found by visual inspection. Electronic electricity meters, often referred to as “smart meters” are one method of detecting electricity theft. Smart meters are able to communicate directly with the electricity supplier, so that the supplier will always have an accurate meter reading. Smart meters, however, are expensive to install. In developing countries in particular, a more cost-effective method is desirable.

Another method of electricity theft is accomplished by bypassing the normal return path of the electrical current. This method involves, first, an electric meter that measures only the current on the return path (also called the neutral wire); and, second, an electricity thief that rewires their electricity system so that the current the thief uses bypasses the expected current return path, thereby bypassing the current measuring device.

Electricity theft can be detected in a number of other ways. One detection method is to provide a current sensor on the current source (i.e. the hot conductor) as well as on the return path (i.e. the neutral conductor). The values measured by the two current sensors can be compared and theft detected by large differences between these two measurements. This method, however, can be costly because it requires two current sensors for each electricity user. Moreover, alternating current (AC) systems employing high voltage require an electrically isolated current sensor, which can be even more costly.

### SUMMARY

In accordance with embodiments of the present invention, systems and methods for detecting electricity theft are provided. In systems where, first, many electricity users are supplied by a single power source, and, second, each electricity user may be switched on and off by software, electricity theft detection may be performed without providing a source sensor (also called a high-side current sensor) for every circuit. Instead, a single high-side current sensor is used to measure the source current to a group of electricity users, and the circuits for the individual electricity users may be switched on in isolation, allowing a single circuit to use this high side sensor and perform a theft detection calculation.

In various embodiments, a method for detecting electricity theft is disclosed. The method comprises providing power to a plurality of end user destinations from one power source. The method further comprises selecting one destination from the plurality of end user destinations for testing, and switching off all of the end user destinations except for the selected destination. The method further comprises sensing the current from the power source and sensing the current returning from the selected destination. The method further comprises determining a difference between the current from the power source and the current returning from the selected destination.

In various embodiments, a system for detecting electricity theft is disclosed. The system comprises a power interface for receiving power from a power source, a source sensor coupled to the power interface for measuring current from the power source, and a plurality of output interfaces for delivering power to a plurality of end user destinations, wherein each of the plurality of output interfaces comprises a return sensor.

In various embodiments, an apparatus for detecting electricity theft is disclosed. The apparatus comprises a power interface for receiving power from a power source, a source sensor coupled to the power interface for measuring current from the power source, and a plurality of output interfaces for delivering power to a plurality of end user destinations, wherein each of the plurality of output interfaces comprises a return sensor.

### DESCRIPTION OF THE DRAWINGS

The novel features of the embodiments described herein are set forth with particularity in the appended claims. The embodiments, however, both as to organization and methods of operation may be better understood by reference to the following description, taken in conjunction with the accompanying drawings as follows:

FIG. 1 illustrates a block diagram of a power distribution system;

FIG. 2 illustrates a system for electricity theft detection via a circuit switch; and

FIG. 3 illustrates a process that may be implemented by the system of FIG. 2 to detect electricity theft.

### DETAILED DESCRIPTION

In the following description, reference is made to the accompanying drawings which illustrate several embodiments disclosed herein. It is understood that other embodiments may be utilized and mechanical, compositional, structural, electrical, and operational changes may be made without departing from the spirit and scope of the present disclosure.

As used herein, the singular forms “a”, “an” and “the” are intended to include the plural forms as well, unless the context indicates otherwise. It will be further understood that the terms “comprises” and/or “comprising” specify the presence of stated features, steps, operations, elements, and/or components, but do not preclude the presence or addition of one or more other features, steps, operations, elements, components, and/or groups thereof.

Certain embodiments will now be described to provide an overall understanding of the principles of the structure, function, manufacture, and use of the devices and methods disclosed herein. One or more examples of these embodiments are illustrated in the accompanying drawings. Those of ordinary skill in the art will understand that the devices and methods specifically described herein and illustrated in the accompanying drawings are non-limiting exemplary embodiments. The features illustrated or described in connection with one exemplary embodiment may be combined with the features of other embodiments. Such modifications and variations are intended to be included within the scope of the present embodiments.

Reference throughout the specification to “various embodiments,” “some embodiments,” “one embodiment,” or “an embodiment”, or the like, means that a particular feature, structure, or characteristic described in connection with the embodiment is included in at least one embodiment. Thus, appearances of the phrases “in various embodiments,” “in some embodiments,” “in one embodiment”, or “in an embodiment”, or the like, in places throughout the specification are not necessarily all referring to the same embodiment. Furthermore, the particular features, structures, or characteristics may be combined in any suitable manner in one or more embodiments. Thus, the particular features, structures, or characteristics illustrated or described in connection with one embodiment may be combined, in whole or in part, with the features structures, or characteristics of one or more other embodiments without limitation. Such modifications and variations are intended to be included within the scope of the present embodiments.

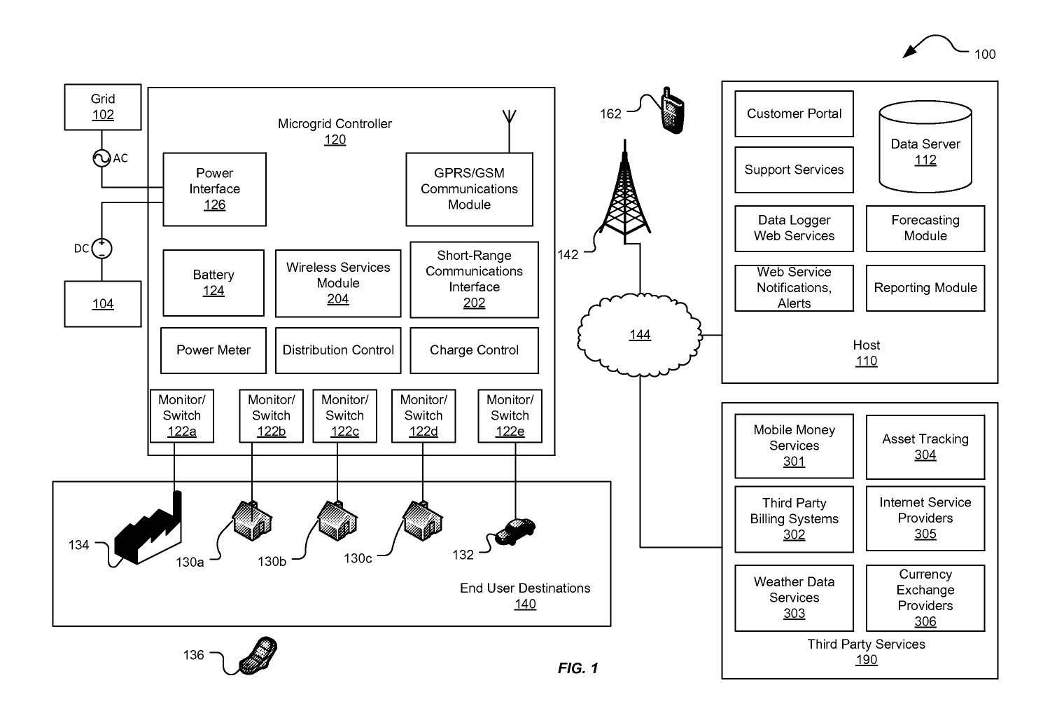

FIG. 1 illustrates a block diagram of a power distribution system 100, in accordance with embodiments disclosed herein. Similar power distribution systems are described in International Patent Publication Number WO 2014/074626, having an International Filing Date of 6 Nov. 2013, the contents of which are incorporated by reference in its entirety. The system 100 includes a microgrid controller 120 for distributing power to end users and a remote computing system (e.g., host system 110) for tracking and managing the power generating assets, including handling payments from and power delivery to the end user destinations. The host system 110 may also provide real-time data and analytics regarding power generation and usage. The host system 110 may communicate with the microgrid controller 120 via existing telecommunications infrastructure.

In accordance with embodiments disclosed herein, the microgrid controller 120 is located in relatively close physical proximity to the end users and is coupled to distribution lines that carry electrical power to the end user destinations. The power may be delivered to the end user destinations via known distribution methods, such as to residential customers having standard power sockets in homes 130a-130c, commercial or industrial customers having power delivered to a business or factory 134, or to any other end user destination, such as an electric vehicle charging station 132. The microgrid controller 120 may include a power interface 126 to receive power from the standard electric grid 102, if access to the grid 102 is available. In addition to or in place of the connection to the grid 102, the microgrid controller 120 may be connected via the power interface 126 to one or more alternate power sources 104, such as a fuel cell, wind turbine, solar power system, or other energy source. The microgrid controller 120 may further include one or more energy storage devices for temporary storage of electricity received from the grid 102 or other power source 104. These energy storage devices may include both devices that store electricity such as batteries 124 and capacitive storage devices. These energy storage devices may also include devices that convert the electricity to another form of energy and then store it, such as inertial storage devices such as flywheels or pumped storage.

The microgrid controller 120 can provide a localized grouping of electricity generation, energy storage, electric power delivery, and Internet services to end users who are not otherwise connected to the power grid 102. In some embodiments, all of this functionality is provided in a single device that can be easily transported to and installed in remote locations. This can be particularly useful in regions where technically skilled personnel are unavailable and the installation, connection, and set-up of multiple components can be challenging.

In accordance with embodiments disclosed herein, each end user destination 140 receives power from a dedicated switch 122a-122e, which monitors power consumption by the end user destination 140 and can initiate or terminate power delivery to the end user destination 140 based on instructions received from the host 110. The power consumption monitors may calculate power consumption based on current and voltage. The current measurement can be based on any current measurement technology, including, e.g., shunt resistor, current transformer or transducer, or Hall Effect sensor. The switch 122a-122e may deliver either AC or DC power, depending on the end user's needs. The switch 122a-122e may be any type of AC or DC switch, including electromechanical devices such as relays or contactors and solid state devices such as, e.g., transistors, silicon controlled rectifiers, and thyristors.

In accordance with embodiments disclosed herein, each end user destination is associated with a communications device, such as, e.g., a mobile phone device 136, tablet computing device, or other computing device configured for user input and data communications. The user may utilize the mobile phone 136 to authorize pre-payment to the host 110 via any of a variety of known payment systems. The communications device may authorize pre-payment via any of a variety of known communications technologies, such as, e.g., a wired network connection, WLAN, or mobile data service, such as, e.g., GPRS or GSM. In some embodiments, the host 110 is configured to receive payments from a plurality of different payment systems, so that different end users on the same microgrid controller 120 may use different forms of payment.

Examples of payment systems include mobile money, such as M-Pesa, scratch card, prepaid phone card, or local agents. In other embodiments, the host 110 may accept payments via transfer of mobile phone minutes

The payment is transmitted via mobile phone tower 142 and the Internet 144 to the host 110, which may be implemented using a cloud computing system located anywhere in the world. When the pre-payment is received by the host 110, the end user destination's account is credited with the pre-payment amount in the data server 112. The host 110 then transmits this pre-payment information to the microgrid controller 120. This transmission may occur via any of a variety of known communications technologies, such as a wired network connection, WLAN, or mobile data service, such as, e.g., GPRS or GSM.

The microgrid controller 120 will monitor the pre-paid balance for each end user destination, as well as that destination's consumption of power. Once the end user destination has utilized enough electricity to have depleted the prepaid credits, the power to that end user destination will be terminated by the microgrid controller 120 using the corresponding switch 122a-122e associated with that end user. This will not affect the other end user destinations receiving power from that microgrid controller 120.

In some embodiments, the mobile device 136 associated with the end user destination 130 will receive a message alerting the user that the amount of prepaid credits is almost consumed and/or reminding the user that the amount of prepaid credits has already been depleted. This may occur once the credit balance reaches a predetermined or programmable minimum value. The message to the mobile device 136 can be delivered via any of a variety of messaging technologies, such as, e.g., Short Message Service (“SMS”), Text Messaging System (“TMS”), voice call, or other messaging service. In the developing world, the preferred messaging technology may be a text messaging service configured for use by low-cost mobile phones. The end user may then utilize the mobile device 136 to transmit additional prepaid amounts to the host 110. This may be done, e.g., by via reply message or by utilizing the same mobile payment service previously used.

In some embodiments, the end users may utilize their mobile devices 136 to check their credit balance and historical usage. This may be performed, e.g., using a browser application, a dedicated power management application, or via messaging service. For example, a user may send a message to a predefined address or containing a predefined string of text (e.g., a text message containing “BALANCE” or “HISTORY”). In response, the host 110 or microgrid controller 120 will cause a reply message to be transmitted containing the requested information.

In some embodiments, the microgrid controller 120 may include a short-range communications interface 202 (e.g., a WLAN or WiFi interface) for communicating with a computing device 162 utilized by a local administrator of the microgrid controller 120. When the local administrator is servicing the microgrid controller 120, the administrator may use a computing device 162, such as a smartphone, tablet computer, laptop computer, or personal computer, to connect with the microgrid controller 120 via the communications interface 202 and perform various administrative functions, such as viewing locally the amount of credit or historical power used per circuit without needing to access the host 110 via the Internet 144 for this information. Other administrative functions include determining when the microgrid controller 120 last synchronized data, such as customer data (e.g., prepaid credits, power consumption, tariffs, etc.) with the host 110, or other diagnostics such as the state of charge of battery 124, average temperature over time of the battery 124, etc.

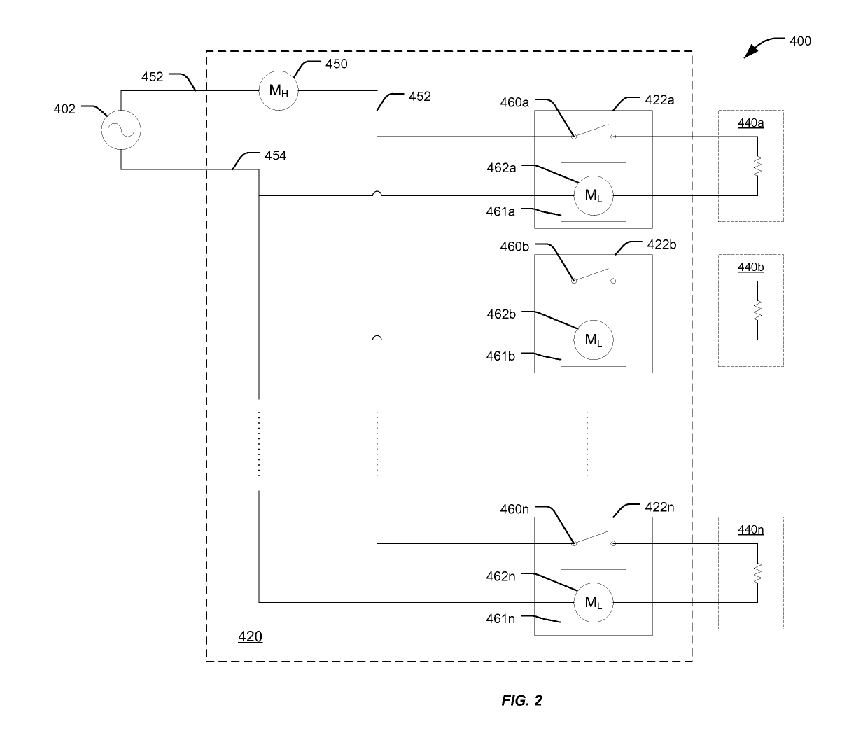

FIG. 2 illustrates a system 400 for electricity theft detection via a circuit switch according to various embodiments. The system and method may be implemented as part of a microgrid controller 420, which is similar to the microgrid controller 120 of FIG. 1. A microgrid controller 420 is not required, however, and the disclosed embodiments are not limited as such. Returning to FIG. 2, the microgrid controller 420 may receive power from the standard electric grid 402, if access to the grid 402 is available. In addition or in place of the connection to the grid 402, the microgrid controller 420 may be connected to one or more alternate power sources (not illustrated).

Current from the power source 402 enters the microgrid controller 420 on an incoming current wire 452 (also called the “hot” wire). In series or in parallel to the incoming current wire 452 is a source sensor 450 (also called a high-side meter). The source sensor 450 may be part of a power interface, such as for instance the power interface 126 illustrated in FIG. 1, or it may be external to the power interface. A current sensor, such as the source sensor 450, is a device that detects and converts current to a measured output voltage, which is proportional to the current through the measured path. There are two methods of sensing current: direct and indirect. Direct sensing is based on Ohm's law, wherein current is measured by measuring the drop in voltage as the current flows through a wire or circuit. Indirect sensing is based on Faraday's and Ampere's law, where current is measured by measuring the magnetic field generated by a current-carrying conductor. The current measurement can be based on any current measurement technology, including, e.g., shunt resistor, current transformer or transducer, or Hall Effect sensor.

Returning to FIG. 2, current from the power source 402 is distributed to one or more monitors/switches 422a-422n, which monitor power consumption by end user destinations 440a-440n and can initiate or terminate power delivery to the end user destination 440a-440n based on control mechanisms in the microgrid controller 420 or instructions received from a host, such as for instance the host 110 illustrated in FIG. 1. Returning to FIG. 2, the monitors/switches 422a-422n may deliver either AC or DC power, depending on the end user's needs. Each monitor/switch 422 comprises a switch 460, which may be any type of AC or DC switch, including electromechanical devices such as relays or contactors and solid state devices such as, e.g., transistors, silicon controlled rectifiers, and thyristors. A switch 460 can be activated by the microgrid controller 420 or by, for instance, a host 110. Each monitor/switch 422 further comprises monitor 461 that comprises a return sensor 462. Current returning from an end user destination 440 is wired through a corresponding monitor/switch 422, where the current can be sensed by the return sensor 462, which is placed in series or parallel with the return wire. The return sensor 462 (also called the low-side meter) is similar to the source sensor 450, though it need not be the exact same type of device. After passing through a monitor/switch 422 current from all the end user destinations 440a-440n is returned to the power source 402 on a common return wire 454 (also called the “neutral” wire).

As discussed above, the monitors/switches 422a-422n can be controlled by the microgrid controller 420 or by a host 110 located remotely from the microgrid controller. The host 110 may also be operable to detect that the microgrid controller 420 has been tampered with. For instance, the microgrid controller may issue a signal to the host 110 if it is opened or otherwise physically tampered with. The host 110 may also be able to detect if the microgrid controller 420 is removed from the system 400. The host 110 may also be able to detect electricity theft between the power source 420 and the microgrid controller 420 by employing, for instance, one or more additional current sensors located between the power source 420 and the microgrid controller 420.

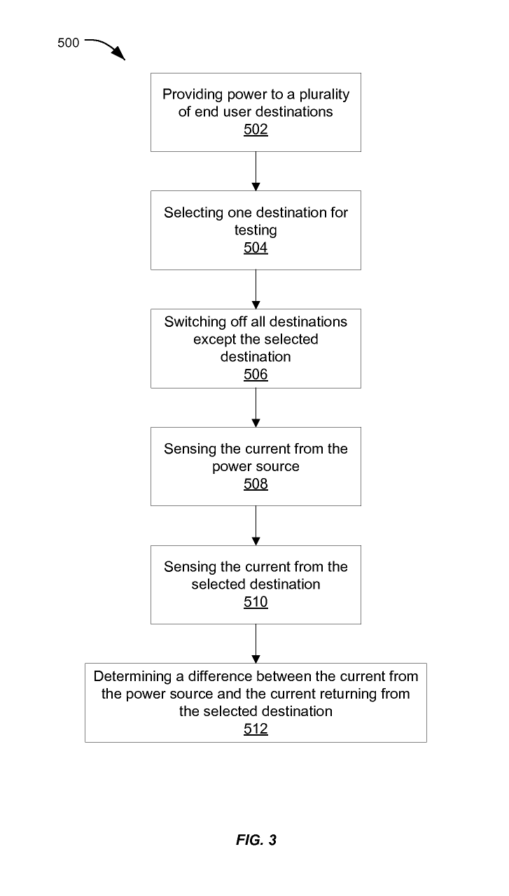

FIG. 3 illustrates a process 500 that may be implemented by the system 400 to detect electricity theft. One or more steps in the process 500 may be implemented by the microgrid controller 420, or by an external system, such as for instance the host 110. In process 500, power is provided 502 to a plurality of end user destinations. The power may be provided, for instance, by the power source 402, and the end user destinations may comprise the end user destinations 440a-440n illustrated in FIG. 4. Returning to FIG. 5, the process 500 comprises selecting 504 one end user destination for testing. All end user destinations except for the selected destination is then switched off 506 using, for example, the switch 460a-460n located in each of the monitors/switches 422a-422n. “Switched off” means that the current to the end user destination 440n is disconnected, such that the end user destination 440 no longer receives power. The current entering the system 400 is then sensed 508 by the source sensor 450. The current returning from the selected destination is also sensed 510 by the return sensor 462 in the switch 460 connected to that destination. The difference between the current entering the system 400 and returning from the system 400 is then determined 512. If the current entering the system 400 is not the same as the current returning from the system 400, then it is probable that the current entering the system 400 is not returning via the return wire, and it is probable that the end user is stealing electricity by one or more of the means described above.

Once the test is complete, all end user destinations 440a-440n are switched back on, meaning that the circuit to each end user destination 440a-440n is closed. The test can be conducted sufficiently quickly so that the end user destinations 440a-440n experience only a negligible interruption in power.

The process 500 illustrated by FIG. 5 can be conducted by selecting each of the end user destinations 440a-440n, one at a time, so that each of the end user destinations 440a-440n are tested within the same interval. This process of testing each end user destination 440 in sequence is sometimes referred to as “round robin” testing, but the end user destinations 440a-440n can also be selected in a random order. Ideally, this testing is conduced during peak electricity usage, such as for instance in the evening, though the test can be conducted at any convenient time. Alternatively or additionally, a specific end user destination 440 that is suspected of electricity theft can be tested in isolation. This test can be conducted during a time that the suspect end user destination 440 is suspected of using electricity, which may not be during peak electricity usage.

Embodiments of the present embodiments may provide various advantages not provided by prior art systems. Multiple households may have power delivered by a single microgrid controller unit, and each household may have its power individually monitored and managed. Above-described embodiments may enable this microgrid controller unit to effectively yet inexpensively detect electricity theft.

While various details have been set forth in the foregoing description, it will be appreciated that the various aspects of the systems and methods for electricity theft detection via a circuit switch may be practiced without these specific details. For example, for conciseness and clarity selected aspects have been shown in block diagram form rather than in detail.

Unless specifically stated otherwise as apparent from the foregoing discussion, it is appreciated that, throughout the foregoing description, discussions using terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Although various embodiments have been described herein, many modifications, variations, substitutions, changes, and equivalents to those embodiments may be implemented and will occur to those skilled in the art. Also, where materials are disclosed for certain components, other materials may be used. It is therefore to be understood that the foregoing description and the appended claims are intended to cover all such modifications and variations as falling within the scope of the disclosed embodiments. The following claims are intended to cover all such modification and variations.

Some or all of the embodiments described herein may generally comprise technologies for various aspects of the disclosed embodiments, or otherwise according to technologies described herein. In a general sense, those skilled in the art will recognize that the various aspects described herein which can be implemented, individually and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken limiting.

With respect to the appended claims, those skilled in the art will appreciate that recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

In certain cases, use of a system or method may occur in a territory even if components are located outside the territory. For example, in a distributed computing context, use of a distributed computing system may occur in a territory even though parts of the system may be located outside of the territory (e.g., relay, server, processor, signal-bearing medium, transmitting computer, receiving computer, etc. located outside the territory).

A sale of a system or method may likewise occur in a territory even if components of the system or method are located and/or used outside the territory. Further, implementation of at least part of a system for performing a method in one territory does not preclude use of the system in another territory.

Although various embodiments have been described herein, many modifications, variations, substitutions, changes, and equivalents to those embodiments may be implemented and will occur to those skilled in the art. Also, where materials are disclosed for certain components, other materials may be used. It is therefore to be understood that the foregoing description and the appended claims are intended to cover all such modifications and variations as falling within the scope of the disclosed embodiments. The following claims are intended to cover all such modification and variations.

In summary, numerous benefits have been described which result from employing the concepts described herein. The foregoing description of the one or more embodiments has been presented for purposes of illustration and description. It is not intended to be exhaustive or limiting to the precise form disclosed. Modifications or variations are possible in light of the above teachings. The one or more embodiments were chosen and described in order to illustrate principles and practical application to thereby enable one of ordinary skill in the art to utilize the various embodiments and with various modifications as are suited to the particular use contemplated. It is intended that the claims submitted herewith define the overall scope.

What is claimed is:

1. A method for detecting electricity theft, comprising:
providing power to a plurality of end user destinations from one power source;
selecting one destination from the plurality of end user destinations for testing;
switching off all of the end user destinations except for the selected destination, wherein each switched off end user destination is disconnected for the power source;
sensing the current from the power source;
sensing the current to the selected destination; and
determining a difference between the current from the power source and the current returning from the selected destination.

2. The method of claim 1, comprising metering each of the plurality of end user destinations with a meter for each circuit, each meter comprising a switch.

3. The method of claim 2, comprising measuring the current returning from the selected destination with a return sensor, wherein a return sensor is integrated into each of the meters.

4. The method of claim 1, comprising measuring the current from the power source with a source sensor.

5. The method of claim 1, comprising measuring each of the plurality of end user destinations one at a time.

6. The method of claim 1, comprising testing at least one of the plurality of end user destinations during peak power usage.

7. The method of claim 1, further comprising selecting a destination from the plurality of end user destinations that is suspected of electricity theft, and testing the selected destination during suspected theft usage.

8. A system for detecting electricity theft, comprising:
a microgrid controller, comprising:
a power interface for receiving power from a power source;
a source sensor coupled to the power interface for measuring current from the power source; and
a plurality of output interfaces for delivering power to a plurality of end user destinations, wherein each of the plurality of output interfaces comprises a return sensor; and
a host, wherein the host is configured to track and manage power generating assets.

9. The system of claim 8, comprising a controller configured to compare a difference between current flowing between the source sensor and each of the return sensors.

10. The system of claim 9, comprising a communications interface for transmitting power consumption information for each end user destination to the host.

11. The system of claim 9, wherein the controller is further configured to measure current flowing through a first one of the output interfaces while suspending power delivery to the remaining output interfaces.

12. The system of claim 9, wherein the controller is further configured to measure current flowing through at least one of the output interfaces during peak power usage.

13. The system of claim 9, wherein the controller is further configured to measure current flowing through an output interface that is suspected of electricity theft, during the suspected theft usage.

14. An apparatus for detecting electricity theft, comprising:
a power interface for receiving power from a power source;
a source sensor coupled to the power interface for measuring current from the power source; and
a plurality of output interfaces for delivering power to a plurality of end user destinations, wherein each of the plurality of output interfaces comprises a return sensor.

15. The apparatus of claim 14, comprising a controller configured to compare a difference between current flowing between the source sensor and each of the return sensors.

16. The apparatus of claim 15, comprising a communications interface for transmitting power consumption information for each end user destination to a remote computing system.

17. The apparatus of claim 15, wherein the controller is further configured to measure current flowing through a first one of the output interfaces while suspending power delivery to the remaining output interfaces.

18. The apparatus of claim 15, wherein the controller is further configured to measure current flowing through at least one of the output interfaces during peak power usage.

19. The apparatus of claim 15, wherein the controller is further configured to measure current flowing through an output interface that is suspected of electricity theft, during the suspected theft usage.
